(19) United States
(12) Patent Application Publication
(10) Pub. No.: US 2025/0392283 A1
(43) Pub. Date: Dec. 25, 2025

(54) COMPOSITE SUBSTRATE AND PREPARATION METHOD THEREOF, ELECTRONIC DEVICE AND MODULE

(71) Applicant: QUANZHOU SANAN INTEGRATED CIRCUIT CO., LTD., Quanzhou (CN)

(72) Inventors: Minghui FANG, Quanzhou (CN); Zhonghe LIN, Quanzhou (CN); Shihwei HUANG, Quanzhou (CN); Yilin LIU, Quanzhou (CN)

(21) Appl. No.: 19/018,137

(22) Filed: Jan. 13, 2025

(30) Foreign Application Priority Data
Jun. 19, 2024 (CN) 2024107923779

(51) Int. Cl. H03H 9/02; H03H 3/08; H03H 9/00; H03H 9/05; H03H 9/25

(52) U.S. Cl. CPC H03H 9/02574; H03H 3/08; H03H 9/0009; H03H 9/02559; H03H 9/0542; H03H 9/0552; H03H 9/25

(57) ABSTRACT

A composite substrate and a preparation thereof, an electronic device and a module are provided. The composite substrate includes: a supporting layer, including a polycrystalline compound; and a piezoelectric layer, including a piezoelectric material and a bonding main surface. The piezoelectric layer is disposed on the supporting layer in a manner that the bonding main surface is bonded to the supporting layer; the piezoelectric layer includes a diffusion area extending from the bonding main surface in a direction gradually facing away from the supporting layer therein; and constituent elements of the polycrystalline compound include characteristic elements different from constituent elements of the piezoelectric material, and the diffusion area includes at least one of the characteristic elements therein. The composite substrate has advantages of TC-SAW and TF-SAW, has high versatility, can reduce production difficulty, and is suitable for mass production.

### CROSS-REFERENCE TO RELATED APPLICATION

This application claims priority to Chinese Patent Application No. 202410792377.9, filed on Jun. 19, 2024, which is herein incorporated by reference in its entirety.

### TECHNICAL FIELD

The disclosure relates to the field of electronic device manufacturing technologies, and more particularly to a composite substrate and a preparation method thereof, an electronic device and a module.

### BACKGROUND

High-performance radio frequency filters used in current communication systems usually include a surface acoustic wave (SAW) resonator, a bulk acoustic wave (BAW) resonator, a film bulk acoustic wave (FBAW) resonator and other types of acoustic resonators. The SAW resonator is taken as an example, the SAW filter is divided into an ordinary surface acoustic wave filter (ordinary SAW), a temperature compensated surface acoustic wave filter (TC-SAW) and a thin film surface acoustic wave filter (TF-SAW). The temperature compensated technology and the thin film technology are introduced into the SAW, its applicable frequency can be increased to a maximum of 3.5 megahertz (GHz) compared to the ordinary SAW, and it is mainly used in mobile ratio frequency front-ends, as well as base stations, automotive electronics and the Internet of Things.

### SUMMARY

A purpose of the disclosure is to provide a composite substrate and a preparation method thereof, an electronic device and a module. The composite substrate can not only introduce temperature compensation effect, but also thin a piezoelectric layer. The composite substrate has advantages of TC-SAW and TF-SAW, has high versatility, can reduce production difficulty, and is suitable for mass production.

An embodiment of the disclosure provides a composite substrate, including a supporting layer and a piezoelectric layer. The supporting layer includes a polycrystalline compound. The piezoelectric layer includes a piezoelectric material and a bonding main surface, and the piezoelectric layer is disposed on the supporting layer in a manner that the bonding main surface is bonded to the supporting layer. The piezoelectric layer includes a diffusion area extending from the bonding main surface in a direction gradually facing away from the supporting layer therein. Constituent elements of the polycrystalline compound include characteristic elements different from constituent elements of the piezoelectric material, and the diffusion area includes at least one of the characteristic elements therein.

An embodiment of the disclosure provides a preparation method of a composite substrate, including a preparing process and a bonding process. The processing process includes: providing a supporting layer and a piezoelectric layer. The supporting layer includes a polycrystalline compound and a supporting main surface; and the piezoelectric layer includes a piezoelectric material and a bonding main surface. The bonding process includes: bonding the supporting layer and the piezoelectric layer in a manner that the bonding main surface is bonded to the supporting main surface, to obtain a bonded substrate. The preparation method of the composite substrate further includes: activating the supporting main surface and the bonding main surface before the bonding process, to make at least one of constituent elements of the polycrystalline compound diffuse from the supporting layer to the piezoelectric layer after the bonding process, to form a diffusion area extending from the bonding main surface in a direction gradually facing away from the supporting layer in the piezoelectric layer, to thereby obtain the composite substrate.

An embodiment of the disclosure further provides an electronic device, including the aforementioned composite substrate or the composite substrate prepared by the aforementioned preparation method of the composite substrate.

An embodiment of the disclosure further provides module, including a wiring substrate, multiple external connection terminals, an integrated circuit component, an inductor, a sealing part, and the aforementioned electronic device.

The above embodiments of the disclosure have one or more of the following beneficial effects. The diffusion area is formed in the piezoelectric layer of the composite substrate, so that the piezoelectric layer of the composite substrate can be thinned to obtain a filter device, and electrical parameters of the filter device can basically achieve parameters of a traditional filter device. A temperature coefficient of frequency (TCF) of the filter device can reduce interference of the filter device by the temperature, and maintain stable performance. Therefore, the composite substrate provided by the above embodiments of the disclosure can not only introduce temperature compensation effect, but also thin the piezoelectric layer. The composite substrate has advantages of TC-SAW and TF-SAW, and the composite substrate has characteristics of high versatility, suitable for mass production, and reduced filter production cost and difficulty since it can be applied to the production of two types of filters.

### BRIEF DESCRIPTION OF DRAWINGS

FIG. 1 illustrates a schematic structural diagram of a composite substrate according to an embodiment of the disclosure.

FIG. 2 illustrates a partially enlarged photograph of the composite substrate according to an embodiment of the disclosure.

FIG. 3 illustrates a further enlarged photograph of a dotted line frame in FIG. 2.

FIG. 4 illustrates a content analysis diagram of tantalum in the composite substrate according to an embodiment of the disclosure.

FIG. 5 illustrates a content analysis diagram of oxygen in the composite substrate according to an embodiment of the disclosure.

FIG. 6 illustrates a content analysis diagram of aluminum in the composite substrate according to an embodiment of the disclosure.

FIG. 7 illustrates a content analysis diagram of magnesium in the composite substrate according to an embodiment of the disclosure.

FIG. 8 illustrates a flowchart of a preparation method of the composite substrate according to an embodiment of the disclosure.

FIG. 9 illustrates a schematic diagram of an electronic device according to an embodiment of the disclosure.

FIG. 10 illustrates a schematic diagram of a module according to an embodiment of the disclosure.

### DETAILED DESCRIPTION OF EMBODIMENTS

### First Embodiment

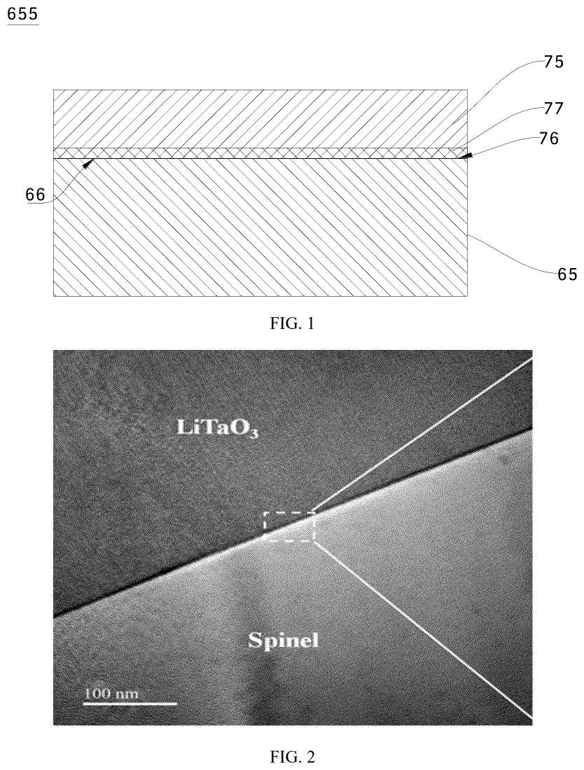

As shown in FIG. 1, the embodiment of the disclosure provides a composite substrate 100, including a supporting layer 10 and a piezoelectric layer 20 bonded to each other. The supporting layer 10 includes a polycrystalline compound and a supporting main surface 11. The piezoelectric layer 20 includes a piezoelectric material and a bonding main surface 21, and the piezoelectric layer 20 is disposed on the supporting layer 10 in a manner that the bonding main surface 21 is bonded to the supporting main surface 11. The piezoelectric layer 20 includes a diffusion area 22 extending from the bonding main surface 21 in a direction gradually facing away from the supporting layer 10 therein. Constituent elements of the polycrystalline compound of the supporting layer 10 include characteristic elements different from constituent elements of the piezoelectric material, and the diffusion area 22 includes at least one of the characteristic elements therein.

Specifically, the supporting layer 10 includes the polycrystalline compound, which can be understood as a main material of the supporting layer 10 being the polycrystalline compound, in other words, the supporting layer 10 is obtained by the polycrystalline compound. The piezoelectric layer 20 includes the piezoelectric material, which can be understood as a main material of the piezoelectric layer 20 being the piezoelectric material, in other words, the piezoelectric layer 20 is obtained by the piezoelectric material. For example, the polycrystalline compound of the supporting layer 10 can be polycrystalline spinel compound, polycrystalline sapphire, polycrystalline aluminum nitride, polycrystalline magnesium oxide, or aluminum oxynitride. The piezoelectric material can be lithium tantalate (LT) or lithium niobate (LN). For example, the supporting layer 10 is a polycrystalline magnesium aluminum spinel substrate, and the piezoelectric layer 20 is a LT substrate. The supporting layer 10 includes polycrystalline magnesium aluminum spinel; magnesium, aluminum and oxygen are constituent elements of the polycrystalline magnesium aluminum spinel; and tantalate, lithium and oxygen are constituent elements of the piezoelectric material, thus the characteristic elements are magnesium and aluminum other than oxygen in the constituent elements of the polycrystalline magnesium aluminum spinel, that is, the diffusion area 22 includes at least one of the magnesium and the aluminum therein. The characteristic elements in the diffusion area 22 can be an atomic or ionic state. Referring to an orientation shown in FIG. 1, the supporting main surface 11 is an upper surface of the supporting layer 10, and the bonding main surface 21 is a lower surface of the piezoelectric layer 20. The piezoelectric layer 20 is disposed above the supporting layer 10, and the bonding main surface 21 and the supporting main surface 11 are bonded to each other. The diffusion area 22 is located on a side of the bonding main surface 21 facing away from the supporting layer 10, that is, above the bonding main surface 21 in FIG. 1.

After experimental verification, the piezoelectric layer 20 of the composite substrate 100 provided by the above embodiment is thinned below 5 microns (μm) to obtain a piezoelectric layer 20 with a thin film state. Interdigital transducer (IDT) electrode process is performed on the piezoelectric layer 20 with the thin film state to obtain a filter device. The filter device is electrically tested to obtain electrical test results. In the electrical test results, some electrical parameters of the filter device can basically achieve parameters of a traditional filter device, a TCF of the filter device can achieve −10 parts per million per Kelvin (ppm/K) to −40 ppm/K, which is conductive to reducing interference of the filter device by the temperature, and maintain stable performance. Therefore, the composite substrate 100 provided by the above embodiment of the disclosure can not only introduce temperature compensation effect, but also thin the piezoelectric layer 20. The composite substrate 100 has advantages of TC-SAW and TF-SAW, and the composite substrate 100 has characteristics of high versatility, suitable for mass production, and reduced filter production cost and difficulty since it can be applied to the production of two types of filters.

In some embodiments, a thickness of the diffusion area 22 is in a range of 1 nanometer (nm) to 1000 nm, for example, 1 nm, 5 nm, 10 nm, 20 nm, 40 nm, 100 nm or 200 nm. Specifically, the thickness of the diffusion area 22 is in a range of 1 nm to 500 nm, more specifically, the thickness of the diffusion area 22 is in a range of 1 nm to 100 nm, and more specifically, the thickness of the diffusion area 22 is in a range of 1 nm to 40 nm. A thickness direction of the diffusion area 22 is a stacking direction of the supporting layer 10 and the piezoelectric layer 20, and the thickness of the diffusion area 22 can also be called a diffusion depth. Within the above thickness ranges, the greater the thickness of the diffusion area 22, the better the temperature compensation effect, which is more conductive to reducing the interference of the filter device by the temperature. Particularly, when the thickness of the diffusion area 22 is in a range of 1 nm to 40 nm, the greater the thickness of the diffusion area 22, the more obvious a trend of increasing the temperature compensation effect.

In some embodiments, the polycrystalline compound of the supporting layer 10 is any one selected from the group consisting of a polycrystalline spinel compound, polycrystalline sapphire, polycrystalline aluminum nitride, polycrystalline magnesium oxide, and aluminum oxynitride.

In some embodiments, the polycrystalline compound of the supporting layer 10 is the polycrystalline spinel compound. For example, a molecular formula of the polycrystalline spinel compound can be expressed as AB₂O₄, A is a metal element, B is another element different from A, and O is oxygen. For example, the polycrystalline compound is the polycrystalline magnesium aluminum spinel, and its chemical formula is MgAl₂O₄, A is magnesium, and B is aluminum.

A metal element in the polycrystalline spinel compound is called a first metal element, and other metal element in the polycrystalline spinel compound is called a second metal element. That is, the polycrystalline compound of the supporting layer 10 is the polycrystalline spinel compound including the first metal element, the second metal element and oxygen. In some embodiments, the diffusion area 22 includes the first metal element and the second metal element therein. For example, the constituent elements of the piezoelectric material of the piezoelectric layer 20 include oxygen, and do not include the first metal element and the second metal element. The first metal element and the second metal element are the aforementioned characteristic elements.

In some embodiments, a weight percentage of the first metal element in the diffusion area 22 is in a range of 1 wt % to 20 wt %, specifically 1 wt % to 10 wt %. A weight percentage of the second metal element in the diffusion area 22 is in a range of 1 wt % to 20 wt %, specifically 1 wt % to 10 wt %.

In some embodiments, a metal activity of the first metal element in the polycrystalline spinel compound is higher than that of the second metal element in the polycrystalline spinel compound, and a difference between the weight percentage of the first metal element and the weight percentage of the second metal element in the diffusion area 22 is in a range of 1 wt % to 5 wt %.

In a specific embodiment, the polycrystalline compound is a polycrystalline magnesium aluminum spinel, a weight percentage of the magnesium in the diffusion area 22 is in a range of 1 wt % to 10 wt %, and a weight percentage of the aluminum in the diffusion area 22 is in a range of 0.5 wt % to 10 wt %.

In some embodiments, the characteristic elements in the constituent elements of the polycrystalline compound of the supporting layer 10 include the aluminum, the diffusion area 22 includes the aluminum therein, and the weight percentage of the aluminum in the diffusion area 22 is in a range of 1 wt % to 20 wt %. More specifically, the weight percentage of the aluminum in the diffusion area 22 is in a range of 1 wt % to 10 wt %. For example, when the polycrystalline compound of the supporting layer 10 is the polycrystalline magnesium aluminum spinel (MgAl₂O₄), the polycrystalline sapphire (Al₂O₃), the polycrystalline aluminum nitride (AlN), or the aluminum oxynitride (AlON), the diffusion area 22 includes the aluminum therein, and the weight percentage of the aluminum is in a range of 1 wt % to 20 wt %.

In some embodiments, the characteristic elements in the constituent elements of the polycrystalline compound of the supporting layer 10 include the nitride, the diffusion area 22 includes the nitride therein, and a weight percentage of the nitride in the diffusion area 22 is in a range of 1 wt % to 10 wt %. More specifically, the weight percentage of the nitride in the diffusion area 22 is in a range of 1 wt % to 5 wt %. For example, the polycrystalline compound of the supporting layer 10 is the polycrystalline aluminum nitride (AlN), or the aluminum oxynitride (AlON), the diffusion area 22 includes the nitride therein, and the weight percentage of the nitride is in a range of 1 wt % to 10 wt %.

For example, the piezoelectric material of the piezoelectric layer 20 is LT or LN, the polycrystalline compound of the supporting layer 10 is the polycrystalline sapphire, a diffusion situation of the aluminum can be observed in the diffusion area 22, and the weight percentage of the aluminum is calculated to be in a range of 1 wt % to 20 wt %. The polycrystalline compound of the supporting layer 10 is the polycrystalline aluminum nitride, diffusion situations of the aluminum and the nitride can be observed in the diffusion area 22, and a weight percentage of the aluminum is calculated to be in a range of 1 wt % to 20 wt %, and a weight percentage of the nitride is calculated to be in a range of 1 wt % to 10 wt %.

In some embodiments, in the composite substrate 100, a conductivity of the piezoelectric layer 20 is in a range of 1×10⁻¹² siemens per centimeter (S/cm) to 1×10⁻⁹ S/cm. A thickness of the piezoelectric layer 20 can be in a range of 150 μm to 250 μm. The piezoelectric layer 20 can be thinned, and a thickness of the thinned piezoelectric layer 20 is smaller than or equal to 5 μm. A thickness of the supporting layer 10 is in a range of 250 μm to 500 μm. The composite substrate 100 can be used to prepare an electronic device 200, and a thickness of the supporting layer 10 in the electronic device 200 can be in a range of 150 μm to 250 μm.

### Second Embodiment

The embodiment of the disclosure further provides a preparation method of a composite substrate, including a preparing process and a bonding process.

In the preparing process (i.e., a step S1), a supporting layer 10 and a piezoelectric layer 20 are provided. The supporting layer 10 includes a polycrystalline compound and a supporting main surface 11. The piezoelectric layer 20 includes a bonding main surface 21.

In the bonding process (i.e., a step S3), the supporting layer 10 is bonded to the piezoelectric layer 20 in a manner that the bonding main surface 21 is bonded to the supporting main surface 11, to obtain a bonded substrate 101.

Specifically, the preparation method of the composite substrate further includes a step S2. In the step S2, the supporting main surface 11 and the bonding main surface 21 are activated before the bonding process S3, so that at least one of constituent elements of the polycrystalline compound can diffuse to the piezoelectric layer 20 after the bonding process S3, a diffusion area 22 extending from the bonding main surface 21 in a direction gradually facing away from the supporting layer 10 is formed in the piezoelectric layer 20, to thereby obtain the composite substrate 100.

The preparation method of the composite substrate provided by the embodiment can be used to prepare the composite substrate 100 of the aforementioned first embodiment. Specifically, the polycrystalline compound of the supporting layer 10 provided in the step S1 can be any one selected from the group consisting of a polycrystalline spinel compound, polycrystalline sapphire, polycrystalline aluminum nitride, polycrystalline magnesium oxide, and aluminum oxynitride. A piezoelectric material of the piezoelectric layer 20 can be LT or LN. Specific settings of the polycrystalline compound of the supporting layer 10 and the piezoelectric material of the piezoelectric layer 20 can refer to the descriptions in the aforementioned first embodiment.

In the step S1, a thickness of the supporting layer 10 is in a range of 250 μm to 500 μm, and a thickness of the piezoelectric layer 20 is in a range of 150 μm to 250 μm. Before the step 1, for example, materials of the supporting layer 10 and the piezoelectric layer 20 are polished, so that surface roughnesses Sa of the supporting main surface 11 and the bonding main surface 21 each are smaller than or equal to 0.5 nm. Before the step S3, for example, a surface of the piezoelectric layer 20 is reduced, so that a conductivity of the bonding main surface 21 reaches 1×10⁻¹² S/m to 1×10⁻⁹ S/m, and there are a lot of oxygen vacancies.

The step 2 can refer to a step (a) shown in FIG. 8, specifically, an ion gun 300 is used to launch argon (Ar) ions to activate the supporting main surface 11 and the bonding main surface 21. After the step S2, the step 3 is performed refer to a step (b) shown in FIG. 8 to obtain the bonding substrate 101. Due to a lot of oxygen vacancies in the surface of the piezoelectric layer 20, active atoms or ions on the surface of the supporting layer 10 can easily diffuse into the piezoelectric layer 20, to thereby form the diffusion area 22, and finally forming the composite substrate 100 shown in a step (c) in FIG. 8.

In some specific embodiments, constituent elements of the polycrystalline compound of the supporting layer 10 include characteristic elements different from constituent elements of the piezoelectric material of the piezoelectric layer 20, and the diffusion area 22 includes at least one of the characteristic elements therein.

In some embodiments, the preparation method of the composite substrate further includes a step S4. After the bonding process (i.e., the step S3), the bonded substrate 101 is annealed. Specifically, a temperature for annealing is in a range of 100 Celsius degrees (° C.) to 300° C. The annealing treatment can accelerate the formation of the diffusion area 22, and promote the diffusion area 22 to reach a suitable diffusion depth (thickness), so that the thickness of the diffusion area 22 can be controlled, which is conductive for mass production, and ensuring the consistency of the diffusion depth. Specifically, the step S4 adopts a low-temperature oxygen-free annealing process, and the oxygen-free environment can prevent resistance of the piezoelectric layer 20 from changing during the annealing process.

In some embodiments, referring to a step (d) shown in FIG. 8, the preparation method of the composite substrate further includes a step S5. After the bonding process S3, the piezoelectric layer 20 is thinned to make a thickness of the piezoelectric layer 20 below 5 μm (i.e., smaller than or equal to 5 μm). Specifically, when the preparation method further includes the step S4, the step S5 is performed after the step S4. In the step S5, the piezoelectric layer 20 is thinned and polished, which can achieve thinning of the piezoelectric layer 20, and is conductive to preparing the TF-SAW device.

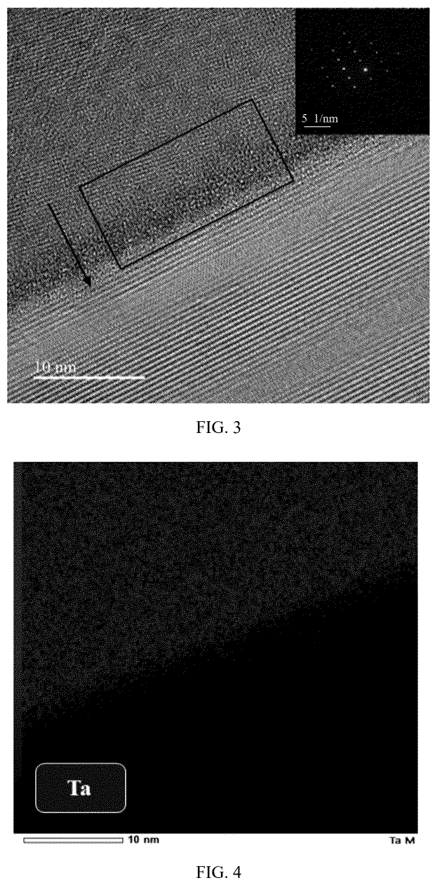

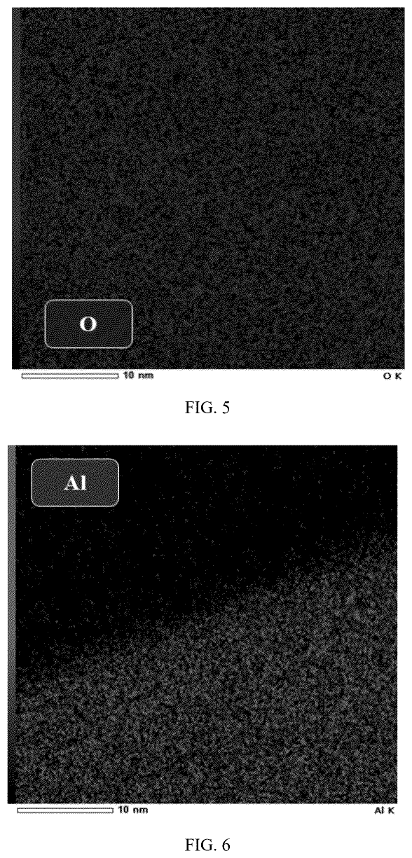

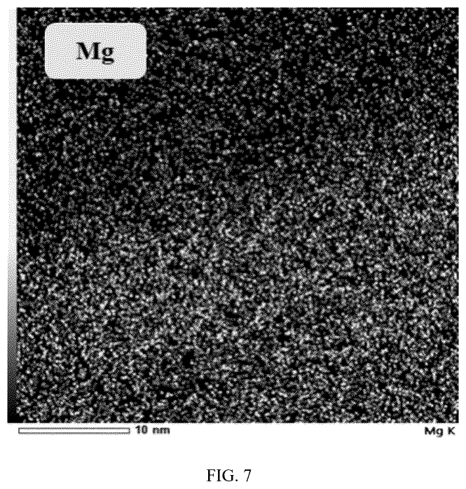

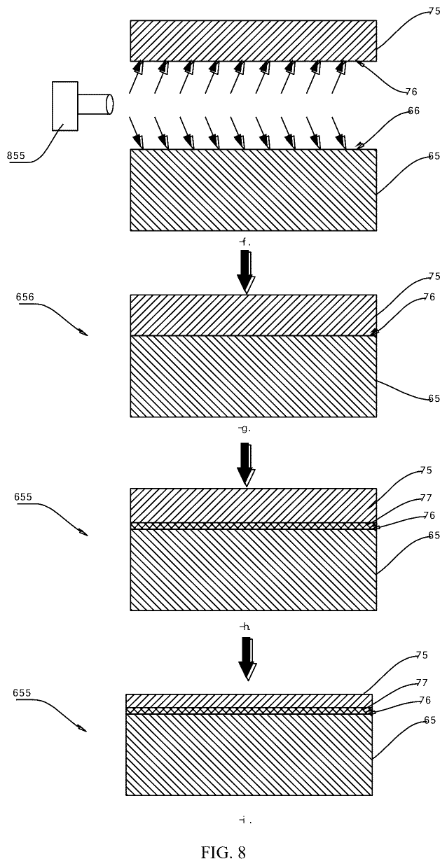

FIGS. 2-7 each illustrate an observe result of the composite substrate 100 prepared by using the preparation method provided by the embodiment in a specific embodiment. In the specific embodiment, the piezoelectric material of the piezoelectric layer 20 is LT (a chemical formula is LiTaO₃), and the polycrystalline compound of the supporting layer 10 is magnesium aluminum spinel (Spinel). As shown in FIG. 2, a dotted line frame captures areas on both sides of a bonding interface between the supporting layer 10 and the piezoelectric layer 20. In FIG. 3, the dotted line frame in FIG. 2 is further enlarged, and a diffusion area 22 (a black solid frame area in FIG. 3) with a length about 5 nm can be seen. An upper right corner (a scale is one-fifth of a nanometer) in FIG. 3 is an atomic state of the diffusion area 22 under observation using a high-magnification scanning transmission electron microscopy (STEM), and it can be seen that the atoms are clearly evenly arranged. Therefore, it can be determined that the diffusion area 22 is a transcrystalline layer, rather than an amorphous state. This transcrystalline layer structure makes heat conduction between the diffusion area 22 and a non-diffusion area (i.e., an area of the piezoelectric layer 20 other than the diffusion area 22) smoother, which is conductive for improvement of TCF. It can be understood that a main component of the diffusion area 22 is still the piezoelectric material of the piezoelectric layer 20, and only some elements diffuse from the supporting layer 10 into the piezoelectric layer 20 to form the diffusion area 22. A direction (i.e., a direction from LT to Spinel) indicated by a black arrow shown in FIG. 3 is a measurement direction to perform element analysis on the both sides of the bonding interface. According to FIG. 4, there is no diffusion on tantalum (Ta) atoms, and there is a clear boundary between LT and Spinel. According to FIG. 5, a diffusion situation of the oxygen (O) atoms cannot be determined. According to FIG. 6, the aluminum with a low concentration diffuses to LT, a diffusion depth is in a range of 1 nm to 1000 nm, and a weight percentage of the aluminum in the diffusion area 22 is measured to be in a range of 0.5 wt % to 10 wt %. According to FIG. 7, the magnesium with a middle concentration diffuses to LT, a diffusion depth is in a range of 1 nm to 1000 nm, and a weight percentage of the magnesium in the diffusion area 22 is measured to be in a range of 1 wt % to 10 wt %. It can be seen that the preparation method of the composite substrate provided by the second embodiment of the disclosure can prepare the composite substrate 100 provided by the aforementioned first embodiment.

Table 1 shows data of the diffusion depth and the weight percentage of each of the magnesium and the aluminum in the diffusion area 22 in the composite substrate 100 (the polycrystalline compound of the supporting layer 10 is the magnesium aluminum spinel) in some embodiments. According to Table 1, when the diffusion depth is smaller than or equal to 40 nm, the greater the diffusion depth, the greater the weight percentages of the magnesium and the aluminum. When the diffusion depth is greater than 40 nm, as the diffusion depth gradually increases, the weight percentages of the magnesium and the aluminum gradually decreases, and a diffusion area 22 with a maximum thickness of 1000 nm can be formed.

TABLE 1

| | Diffusion depth | | | | | |
|---|---|---|---|---|---|---|
| | 20 nm | 40 nm | 100 nm | 300 nm | 500 nm | 1000 nm |
| Weight | ≤7.1% | ≤7.5% | ≤5.9% | ≤4.3% | ≤2.5% | ≤1.0% |
| percentage | | | | | | |
| of Mg | | | | | | |
| Weight | ≤4.2% | ≤4.4% | ≤2.6% | ≤1.1% | ≤0.8% | ≤0.5% |
| percentage | | | | | | |
| of Al | | | | | | |

The effects of the composite substrates 100 prepared by the preparation method of the composite substrate are described by the following experiments 1 to 4. In the experiment 1, it is ensured that only a few atoms or ions on the surface of the piezoelectric layer 20 and the supporting layer 10 are activated and bonded, an IDT electrode is prepared based on the obtained composite substrate 100, and is used to an electrical test of the filter. In the experiment 2, it is ensured that some atoms or ions on the surface of the piezoelectric layer 20 and the supporting layer 10 are activated and bonded, an IDT electrode is prepared based on the obtained composite substrate 100, and is used to an electrical test of the filter. In the experiment 3, it is ensured that most atoms or ions on the surface of the piezoelectric layer 20 and the supporting layer 10 are activated and bonded, an IDT electrode is prepared based on the obtained composite substrate 100, and is used to an electrical test of the filter. In the experiment 4, it is ensured that almost atoms or ions on the surface of the piezoelectric layer 20 and the supporting layer 10 are activated and bonded, an IDT electrode is prepared based on the obtained composite substrate 100, and is used to an electrical test of the filter.

Results of the electrical tests of the experiments 1 to 4 are shown in Table 2.

TABLE 2

| | Experiment 1 | Experiment 2 | Experiment 3 | Experiment 4 |
|---|---|---|---|---|
| Content of magnesium | <1.0 wt % | 5.7 wt % | 7.1 wt % | 7.5 wt % |
| in diffusion area | | | | |
| Content of aluminum | <0.5 wt % | 2.4 wt % | 4.2 wt % | 4.4 wt % |
| in diffusion area | | | | |
| Thickness of | 0 nm to | 6 nm to | 15 nm to | 30 nm to |
| diffusion area | 5 nm | 10 nm | 25 nm | 40 nm |
| Yield | 92.17% | 93.43% | 96.21% | 95.20% |
| Frequency difference | 2.15 | 2.07 | 2.2 | 2.09 |
| Insertion loss | 0.39 | 0.38 | 0.43 | 0.36 |
| difference | | | | |
| TCF (ppm/K) | −13.9 | −13.7 | −13.2 | −12.5 |

In Table 2, the frequency difference is a difference between a frequence of a receive terminal of the filter and a designed standard frequence, and the insertion loss difference is a difference of an insertion loss of the receive terminal and an insertion loss of a transmitting terminal. It can be seen from data of the experiments 1 to 4 that thickness (i.e., the diffusion depths of the magnesium and the aluminum) change of the diffusion area 22 has little effect on electrical parameters, and can meet the requirements of the traditional TC-SAW and TF-SAW, and the thickness of the formed diffusion area 22 increases TCF significantly. After the metal ions diffuse into the piezoelectric layer 20, the oxygen vacancies on the surface of the piezoelectric layer 20 are supplemented, and the thermal conductivity and electrical conductivity of the device are significantly changed, resulting in a certain improvement in the characteristics of the filter device in TCF. Increasing the thickness of the diffusion area 22 is conducive to reducing the interference of the filter device by temperature and maintaining stable performance. Therefore, the composite substrate 100 prepared by the aforementioned preparation method can not only introduce temperature compensation effect, but also thin the piezoelectric layer 20, and has the advantages of both TC-SAW and TF-SAW.

### Third Embodiment

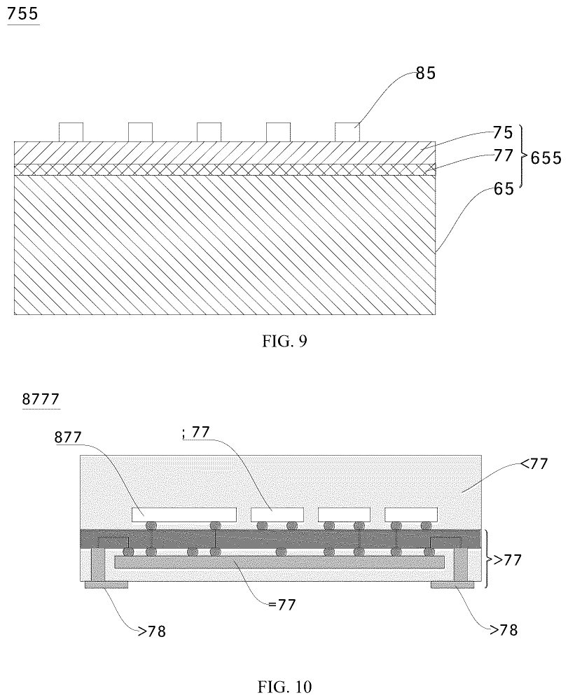

The third embodiment of the disclosure provides an electronic device 200, including any one of the composite substrates 100 in the aforementioned first embodiment, or including the composite substrate 100 prepared by the preparation method of the composite substrate in the aforementioned second embodiment. The specific descriptions of the composite substrate 100 can refer to the descriptions of the aforementioned first embodiment and second embodiment, and will not be repeated here. The electronic device 200, for example, further includes electrodes 30 disposed on a side of the piezoelectric layer 20 facing away from the supporting layer 10. As shown in FIG. 9, the electrode 30, for example, can be an IDT electrode, and the electronic device 200, for example, can be a SAW device.

In some embodiments, the electronic device 200 is electrically tested, and a temperature coefficient of frequency of the electronic device 200 is in a range of −10 ppm/K to −40 ppm/K.

The electronic device 200 provided by the third embodiment of the disclosure includes the composite substrates 100 of the aforementioned first embodiment and second embodiment, has the same beneficial effects of the aforementioned first embodiment and second embodiment, and will not be repeated here.

As shown in FIG. 10, the third embodiment of the disclosure further provides a module 1000, including a wiring substrate 700, multiple external connection terminals 701, an integrated circuit component 600, an electronic device 200 (including the composite substrate 100), an inductor 400 and a sealing part 500. The multiple external connection terminals 701 are formed on a surface of the wiring substrate 700, and the multiple external connection terminals 701 are installed on a motherboard of a preset mobile communication terminal. The integrated circuit component 600 (also referred to as IC) is installed inside the wiring substrate 700. The integrated circuit component 600 includes a switching circuit and a noise amplifier. The electronic device 200 is installed on a main surface of the wiring substrate 700. The inductor 400 is used for impedance matching. For example, the inductor 400 is an integrated passive device (IPD). The sealing part 500 is used to seal multiple electronic components including the electronic device 200 on the wiring substrate 700.

The module 1000 provided by the embodiment includes the electronic device 200, has the same beneficial effects of the electronic device 200, and will not be repeated here.

The above descriptions are merely some of the embodiments of the disclosure and does not limit the disclosure in any form. Although the disclosure has been disclosed as some of the embodiments as above, it is not used to limit the disclosure. Any those skilled in the art can make some changes or modify the technical contents disclosed above into equivalent embodiments without departing from the scope of the technical solution of the disclosure. However, any simple modification, equivalent change and modification made to the above embodiments according to the technical essence of the disclosure without departing from the content of the technical solution of the disclosure still fall within the scope of the technical solution of the disclosure.

What is claimed is:

1. A composite substrate, comprising:
a supporting layer, comprising a polycrystalline compound; and
a piezoelectric layer, comprising a piezoelectric material and a bonding main surface; wherein the piezoelectric layer is disposed on the supporting layer in a manner that the bonding main surface is bonded to the supporting layer; the piezoelectric layer comprises a diffusion area extending from the bonding main surface in a direction gradually facing away from the supporting layer therein; and constituent elements of the polycrystalline compound comprise characteristic elements different from constituent elements of the piezoelectric material, and the diffusion area comprises at least one of the characteristic elements therein.

2. The composite substrate as claimed in claim 1, wherein a thickness of the diffusion area is in a range of 1 nm to 1000 nm.

3. The composite substrate as claimed in claim 1, wherein the polycrystalline compound is any one selected from the group consisting of a polycrystalline spinel compound, polycrystalline sapphire, polycrystalline aluminum nitride, polycrystalline magnesium oxide, and aluminum oxynitride.

4. The composite substrate as claimed in claim 3, wherein the polycrystalline compound is the polycrystalline spinel compound comprising a first metal element, a second metal element and oxygen, and the diffusion area comprises the first metal element and the second metal element therein.

5. The composite substrate as claimed in claim 4, wherein a weight percentage of the first metal element in the diffusion area is in a range of 1 wt % to 20 wt %, and a weight percentage of the second metal element in the diffusion area is in a range of 1 wt % to 20 wt %.

6. The composite substrate as claimed in claim 5, wherein a difference between the weight percentage of the first metal element and the weight percentage of the second metal element in the diffusion area is in a range of 1 wt % to 5 wt %, and a metal activity of the first metal element is higher than that of the second metal element.

7. The composite substrate as claimed in claim 3, wherein the polycrystalline compound is a polycrystalline magnesium aluminum spinel, a weight percentage of magnesium in the diffusion area is in a range of 1 wt % to 10 wt %, and a weight percentage of aluminum in the diffusion area is in a range of 0.5 wt % to 10 wt %.

8. The composite substrate as claimed in claim 1, wherein the characteristic elements comprise aluminum, and a weight percentage of the aluminum in the diffusion area is in a range of 1 wt % to 20 wt %.

9. The composite substrate as claimed in claim 1, wherein the characteristic elements comprise nitride, and a weight percentage of the nitride in the diffusion area is in a range of 1 wt % to 10 wt %.

10. The composite substrate as claimed in claim 1, wherein the diffusion area is a transcrystalline layer.

11. The composite substrate as claimed in claim 1, wherein the piezoelectric material is lithium tantalate or lithium niobate; and a thickness of the piezoelectric layer is smaller than or equal to 5 μm.

12. The composite substrate as claimed in claim 1, wherein a thickness of the supporting layer is in a range of 250 μm to 500 μm.

13. An electronic device, comprising the composite substrate as claimed in claim 1.

14. The electronic device as claimed in claim 13, a temperature coefficient of frequency of the electronic device is in a range of −10 parts per million per Kelvin (ppm/K) to −40 ppm/K.

15. The electronic device as claimed in claim 13, wherein the electronic device further comprises electrodes disposed on a side of the piezoelectric layer facing away from the supporting layer, and the electrodes each are an interdigital transducer (IDT) electrode.

16. The electronic device as claimed in claim 13, wherein the electronic device is a surface acoustic wave (SAW) device.

17. The electronic device as claimed in claim 13, wherein a thickness of the supporting layer in the electronic device is in a range of 150 μm to 250 μm.

18. A module, comprising: a wiring substrate, a plurality of external connection terminals, an integrated circuit component, an inductor, a sealing part, and the electronic device as claimed in claim 13.

19. The module as claimed in claim 18, wherein the plurality of external connection terminals are formed on a surface of the wiring substrate; the integrated circuit component is installed inside the wiring substrate; the electronic device is installed on a main surface of the wiring substrate; the inductor is configured for impedance matching; and the sealing part is configured to seal a plurality of electronic components comprising the electronic device on the wiring substrate.

20. The module as claimed in claim 18, wherein the inductor is an integrated passive device (IPD).
